(19) United States
(12) Patent Application Publication
(10) Pub. No.: US 2011/0012760 A1
(43) Pub. Date: Jan. 20, 2011

(54) TOUCH SENSING DEVICE, TOUCH SCREEN DEVICE INCLUDING A TOUCH SENSING DEVICE, MOBILE DEVICE AND METHOD FOR SENSING A TOUCH ON A TOUCH SENSING DEVICE

(75) Inventor: Gunnar KLINGHULT, Lund (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 12/502,371

(22) Filed: Jul. 14, 2009

(51) Int. Cl. H03M 11/02

(52) U.S. Cl. 341/32

(57) ABSTRACT

The present invention relates to a touch sensing device, touch screen device, mobile device and method for sensing a touch and, in particular, to a touch sensing device usable as user interface for controlling various functions in different devices to provide additional and more flexible input operations. The touch sensing device comprises a cover layer defining a touch area, a first winding placed on one side of said cover layer and extending over at least a part of said touch area, and a second winding placed on the same side of said first winding, being spaced apart from said first winding, wherein said first and second windings and said cover layer are arranged so that a coupling of a magnetic field generated by a current supplied to said first winding varies in response to a force onto the touch area.

### FIELD OF THE INVENTION

The present invention relates to a touch sensing device, touch screen device comprising a touch sensing device, mobile device and method for sensing a touch on a touch sensing device. In particular, the touch sensing device may be used as user interface for controlling various functions in different devices, such as mobile devices.

### BACKGROUND

Different kinds of sensors serving as user interfaces in devices, such as mobile devices, are known in the art for sensing an input action of a user. In touch sensors, the input is performed via touching a sensor surface with a finger or stylus. Therefore, these touch sensors provide a user interface or man-machine interface to control various functions of the device having a touch sensor incorporated therein.

Known touch sensors work by reacting to a change in capacitance affected by the presence of a finger or a stylus of a user. For example, these known touch sensors comprise two layers with capacitive components, wherein these components are connected with each other horizontally in the first layer and vertically in the second layer to provide a matrix structure enabling to sense a position in x,y-coordinates of where the sensor is touched. In capacitive touch panels, the capacitive components of one layer forms one electrode of a capacitor and the finger or stylus forms another electrode.

For instance, the so-called CapTouch Programmable Controller for Single Electrode Capacitance Sensors AD7147 manufactured by Analog Devices, Norwood, Mass., U.S.A. (see Data Sheet, CapTouch™ Programmable Controller for Single Electrode Capacitance Sensors, AD7147, Preliminary Technical Data, 06/07—Preliminary version F, 2007 published by Analog Devices, Inc) may be used to measure capacitance.

Recent applications, such as multi-touch applications, require that more than one position on a touch sensor is touched and sensed, e.g. to determine a section of an image on a display that is to be magnified. As applications become more complex, new improved user interfaces are needed.

Therefore, it is desirable to provide a novel touch sensing device, touch screen device, mobile device and method allowing additional and more flexible input operations.

### DISCLOSURE OF INVENTION

A novel touch sensing device, touch screen device, mobile device and method for sensing a touch are presented and defined in the independent claims. Advantageous embodiments are defined in the dependent claims.

An embodiment of the invention provides a touch sensing device comprising a cover layer defining a touch area, a first winding placed on one side of the cover layer and extending over at least a part of the touch area and a second winding placed on the same side of said first winding. The second winding is spaced apart from the first winding. Further, the first and second windings and the cover layer are arranged so that a coupling of the magnetic field generated by a current supplied to the first winding varies in response to a force onto the touch area.

Accordingly, it is not only possible to sense whether a force is applied onto the touch area, but the force exerted on the touch area may also be estimated depending on the variation in the coupling, i.e. the change in the spacing between the first and second windings. Therefore, the change in coupling may serve as an input operation, e.g. in a user interface, to trigger a certain function of a device being connected to or comprising the touch sensing device.

In one embodiment, a measuring section is provided for measuring a voltage of the second winding induced by the current supplied to the first winding and by a change in the spacing between the first and second windings due to a force. Accordingly, a simple voltage measurement can be provided to be used to estimate the force onto the touch area.

In one embodiment, a determination section is provided for determining a signal level based on the induced voltage depending on the extent of the change in the spacing. Accordingly, a stable signal level may be obtained, e.g. after low-pass filtering the induced voltage, which depends on the extent of the change in the spacing. Thus, calibration may be performed to indicate or at least estimate the magnitude of the applied force. For example, the speed of a scrolling operation on a display may be controlled so that the speed of scrolling is increased by increasing the force on the touch area.

In one embodiment, a touch sensor is placed between the cover layer and the first and second windings to sense a position touched on the touch area. Accordingly, in addition to an input operation in the z-direction substantially perpendicular to the touch area, other input operations in an x-y-plane, such as obtaining x,y-coordinates of a location, can be obtained.

In one embodiment, a controller is provided to control the supply of current to the first winding depending on whether the touch sensor senses a touch or not. The controller may be adapted to control the supply of the current, e.g. from a power supply, so that a current is supplied if a touch is sensed by a touch sensor. Accordingly, the touch sensing function in z-direction can be activated and deactivated so as to reduce power consumption, since no current flows through the first winding if no finger or stylus is present for touching on the touch area.

In one embodiment, the current to be supplied to the first winding is an alternating current and in another embodiment the current is a direct current. Accordingly, several possibilities exist to realise the touch sensing device. For example, when an alternating current is supplied to the first winding, an alternating voltage is induced in the second winding so as to produce a change in voltage on the side of the second winding if the spacing is changed.

In one embodiment, the spacing between the first winding and the second winding is between 0.05 mm and 0.5 mm and preferably between 0.1 mm and 0.2 mm. Accordingly, the touch sensing device can be made thin and sensitive to changes in the spacing.

In one embodiment, at least one of the first winding and the second winding expands in a plane. Accordingly, the touch sensing device can be made very thin.

In one embodiment, at least one of the first winding and second winding is shielded by a thin foil. Accordingly, the windings may be shielded individually with a thin metallic foil which will not affect the magnetic field.

In one embodiment, the second winding is placed between the cover layer and the first winding. Accordingly, the first winding carrying the primary current is spaced further apart from a touch sensor or display assembly comprising electronics that may be influenced by the magnetic field.

In one embodiment, the cover layer is at least partly made of a transparent material, such as glass or some type of plastic. Accordingly, when using a transparent, i.e. light-transmissive, material, a display can be placed between the cover layer and the windings and thus the display can still be viewed from a user from the outside.

According to another embodiment, a touch screen device is provided comprising one of the above-described touch sensing devices and a display assembly placed between the cover layer and the first and second windings. Accordingly, a user may be prompted by a message or other information displayed on the display assembly to touch the touch area, i.e. apply a certain force, so as to enable an input operation in z-direction.

According to another embodiment, a mobile device is provided comprising one of the above-described touch sensing devices or the touch screen device. Accordingly, a mobile device may be provided with a novel type of user interface, wherein an input operation is dependable on a force or certain magnitude of the force applied to the touch area.

Another embodiment of the invention provides a method for sensing a touch on a touch sensing device with a touch area and first and second windings. The method comprises the steps of supplying a current to the first winding, applying a force onto the touch area to vary a coupling of a magnetic field generated by the current so as to induce a voltage in the second winding, and determining a signal level based on the induced voltage. Accordingly, an input operation may be provided, which depends on the force applied to the touch area.

### BRIEF DESCRIPTION OF THE DRAWINGS

Embodiments of the invention will be described with respect to the following appended figures.

FIG. 1A illustrates a touch sensing device and elements thereof according to an embodiment of the invention.

FIG. 1B illustrates a touch sensing device and elements thereof when a force is applied according to an embodiment of the invention.

FIG. 2 illustrates a flow diagram of a method for sensing a touch on a touch sensing device according to an embodiment of the invention.

FIG. 3 illustrates a touch sensing device according to another embodiment of the invention in more detail.

FIG. 4 illustrates elements of a touch screen device comprising a touch sensing device and a display assembly according to another embodiment of the invention.

### DESCRIPTION OF THE EMBODIMENTS

The further embodiments of the invention are described with reference to the figures. It is noted that the following description contains examples only and should not be construed as limiting the invention.

In the following, similar or same reference signs indicate similar or same elements.

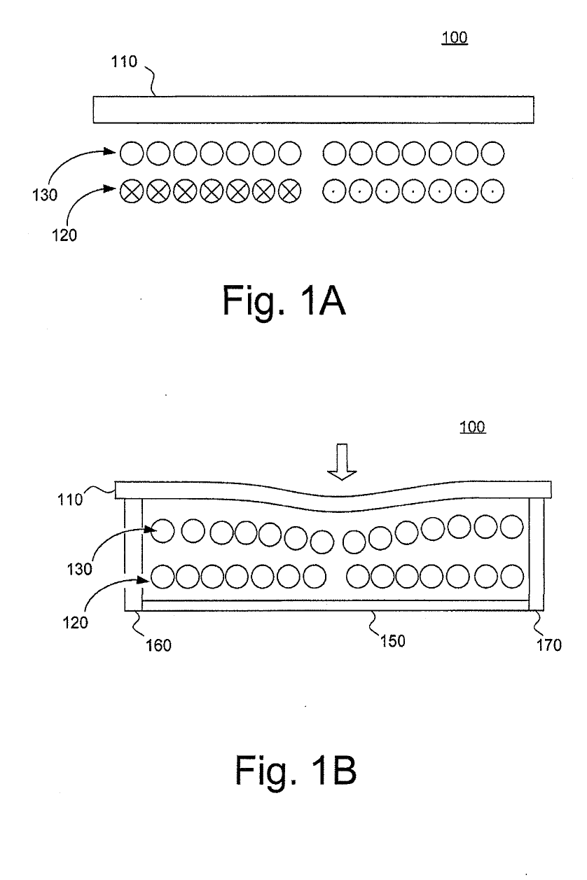

FIG. 1A illustrates elements of a touch sensing device 100 according to an embodiment of the invention. FIG. 1B illustrates the touch sensing device 100 when a force is applied. In detail, the touch sensing device 100 comprises a cover layer 110, a first winding 120 and a second winding 130.

The cover layer 110 is a top layer defining a touch area, onto which a force exerted by a finger, hand, stylus or other object can be applied.

The first winding 120, such as a winding of a coil, is placed on one side of the cover layer 110 and extends over at least a part of the touch area. The second winding 130 is placed on the same side as the first winding 120. Preferably, the second winding overlaps at least partially with the first winding 120. In particular, the larger the overlap of the windings the stronger the induction effect described below.

As can be seen in the embodiment described with respect to FIG. 1A, the first and second windings 120, 130 are placed underneath the cover layer 110 and expand in a plane to enable thin planar-shaped coils. If the windings are assumed to be substantially of a circular shape, the first winding and/or the second winding may expand in radial direction in the plane, which is substantially parallel to the cover layer 110. However, the windings are not limited to a substantially circular shape and any type of conductor loop can be used as a winding that produces a magnetic field when a current is supplied.

Further, as can be seen in FIG. 1A, the first winding 120 and the second winding 130 are spaced apart from each other so as to form a spacing between the first and second winding in an axial direction.

In particular, the first and second windings 120, 130 and the cover layer 110 are arranged so that a coupling of a magnetic field generated by a current supplied to the first winding 120 varies in response to a force onto the touch area changing the spacing.

In FIG. 1A the cover layer 110, the first winding 120 and the second winding 130 are shown substantially parallel to each other. However, to obtain a variation of a coupling of the magnetic field in response to a force onto the touch area, which changes the spacing in between the first and second windings, a parallel arrangement is not necessary and several kinds of orientations may be used as long as a force onto the touch area changes the spacing between the two windings and thus a coupling of a magnetic field of one of the windings.

Furthermore, if it is assumed that the current for producing a magnetic field is supplied to the first winding 110, the same effect of a variation in the coupling of the magnetic field may be achieved whether the first winding is placed between the cover layer 110 and the second winding 130 or underneath both the cover layer 110 and the second winding 130.

In more detail, when a current is supplied to the first winding and a force is applied onto the touch area to change the spacing between the first winding 120 and the second winding 130, a voltage is induced in the second winding 130. If an alternating current is used, the principles of a transformer largely apply to the touch sensing device 100 of FIGS. 1A and 1B and thus an induced voltage may be obtained by the coupling coefficient K according to the following formula:

|V_{sec}|:=ω·Iₚᵣᵢₘ·K·\sqrt{L1·L2}

Here the coupling coefficient K is for an air winded transformer determined by the spacing between the windings, and V_{sec} is the voltage in the second winding, i.e. the secondary winding of a transformer, ω is the frequency and Iₚᵣᵢₘ is the current in the first winding, i.e. the primary winding of a transformer and L1 and L2 are the inductances of the first and second winding. Accordingly, a force applied to touch sensing device may change the spacing and thus the coupling coefficient K.

For example, the coupling of the magnetic field generated by the current in the first winding 120 constitutes the coupling coefficient, or any other parameter proportional to the coupling coefficient or the induced voltage. Therefore, a force applied to the cover layer 110 can be estimated by measuring the voltage induced in the second winding.

When using an alternating current, the magnetic field generated by the electric alternating current varies in time and thus the magnetic flux changes in time, which is experienced by the second winding. Therefore, there is inductive coupling within the second winding and a current and thus a voltage is induced in the second winding 130. This induced voltage changes when the distance between the first and second windings is changed, e.g. due to a force applied on the touch area of the cover layer 110 so that the change in voltage may be used as an estimation of the force. With calibration, the touch sensing device may thus provide a value of the force expressed in Newton or the value of the force may be expressed in a percentage change compared to a reference value.

In contrast thereto, if a direct current is used, the induced voltage will be zero if there is no change in the spacing between the windings, but once the spacing between the windings is changed, an induced voltage can be measured due to a change in the magnetic flux as experienced by the second winding. In particular, an induced voltage increases with the change in spacing and decreases again to zero when the relative movement between the windings stops.

The change in the spacing between the first winding 120 and the second winding 130 is schematically illustrated in FIG. 1B, in which a force is applied on the top of the touch area of the cover layer 110, indicated by the arrow.

In FIG. 1B, the cover layer is made of a flexible and preferably resilient material which may recover the same shape or substantially the same shape after an interaction with a force. Here, the force exerted by a finger, a hand, a stylus or any other object on the touch area of the cover layer 110 bends the cover layer so as to push the second winding 130 closer to the first winding 120. To achieve this, no layer (cover layer 110 and second winding 130 are adjacent to each other) or a flexible layer is provided between the cover layer 110 and the second winding 130 and the spacing between the first winding 120 and the second winding 130 is constituted by an air gap or filled out with a preferably isolating material (not shown) that is elastic to change its thickness when a force is applied.

On the other hand, the first winding 120 may be placed on a stiff layer 150 so that the position of the first winding does not move when a force is applied and thus a distance between the first winding 120 and the second winding 130 can be changed when applying a force to the cover layer 110. The spacing defining the distance between the windings can be between 0.05 mm and 0.5 mm and preferably between 0.1 mm and 0.2 mm so as to realise a very thin structure that is still sensitive to a force applied thereto.

In FIG. 1B, the side walls 160 and 170 of the touch sensing device 100 are assumed to be relatively stiff so that the sensitivity of the touch sensing device 100 may vary depending on where the force is applied, namely on the middle or on the left or right side of the cover layer. This difference is, however, predictable and several ways of compensating for this difference in sensitivity can be thought of.

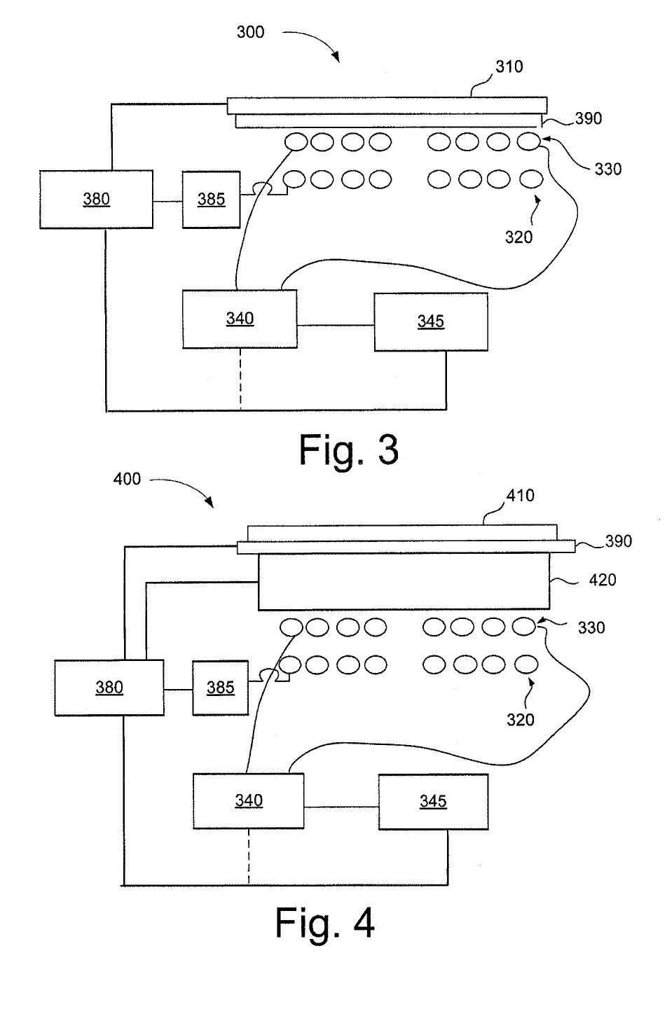

For example, when knowing the x,y-coordinates of where on the touch area the force is applied, e.g. by using a touch sensor as explained in FIG. 3, a look-up table may be used where the x,y-coordinates are used as input parameters.

Further, only a relative measurement of the forces are required in many applications, namely a user may press with a certain force to indicate a single click and with double the force to indicate a double click, so that calibration is not necessarily needed and changes in sensitivity depending on different stiffnesses where the force is applied on the cover layer 110 can be handled successfully.

It is noted that it is not essential that the cover layer 110 is made of a flexible and/or resilient material, but may also be made of a stiff and rigid material. In this case, the side walls 160 and 170 of the touch sensing device 100 may be made partly flexible or elastic so that when applying a force to the touch area of the cover layer 110, the side walls 160 and 170 may be shortened in z-direction to change the spacing.

As described above, the touch sensing device 100 enables the detection of forces of different magnitudes which can be used as input parameters for different input operations. Hence, the touch sensing device 100 may be used as a touch pad. For example, an external display may be connected to the touch sensing device serving as a touch pad, wherein the display shows a scroll list and the speed of scrolling up or down the list is determined by the magnitude of the force applied to the touch sensing device 100.

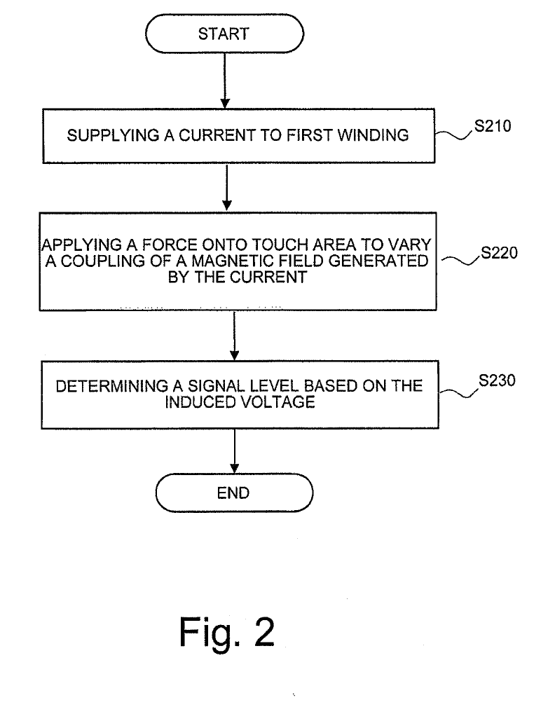

In the following, operations of a method for sensing a touch on a touch sensing device, such as on the touch sensing device 100, will be described with respect to FIG. 2.

In a first step S210, a current is supplied to the first winding 120. As described above, an alternating current is preferably used generating a magnetic field changing in time so that the magnetic field of the first winding 120 generates an inductive coupling with respect to the second winding 130.

Further, in step S220 a force is applied to the touch area of the cover layer 110, as shown in FIG. 1B, so as to change the spacing between the first winding 120 and the second winding 130 due to a relative movement of the second winding 130 in a direction to the first winding 110. As described above, the coupling is dependent on the arrangement of the two windings, in particular the spacing between them, and changes once the spacing changes so that, as shown in the formula above, a voltage is induced in the second winding 130 due to the variation in the coupling. The coupling of the magnetic field generated by the current in the first winding 120 may constitutes the coupling coefficient, or any other parameter proportional to the coupling coefficient or the induced voltage. Therefore, a force applied to the cover layer 110 can be estimated by measuring the voltage induced in the second winding.

In step S230, a signal level is determined based on the induced voltage in the second winding 130. For example, the signal level is the signal level or proportional thereto of the induced voltage measured at the second winding after amplification and low-pass filtering thereof. In particular, when using an alternating current in the first winding 120, low-pass filtering will result in a DC voltage from the induced AC voltage so as to obtain a stable voltage value when no force is applied and a change in the voltage value when a force is applied.

In the following, a specific embodiment of a touch sensing device will be explained with respect to FIG. 3. In FIG. 3 the touch sensing device 300 comprises a cover layer 310, a first winding 320 and a second winding 330. The cover layer 310, the first winding 320 and the second winding 330 may be similar or even identical to the cover layer 110, the first winding 120 and the second winding 130 described with respect to FIGS. 1A and 1B so that a description thereof is omitted for brevity. In addition thereto, the touch sensing device 300 comprises a measuring section 340, a determination section 345, a controller 380, a power supply 385 and a touch sensor 390.

The measuring section 340 is adapted to measure a voltage of the second winding 330 induced by the current supplied to the first winding 320 and the change in the spacing between the first and second windings. In detail, as described above, if a force is applied to the cover layer 310, the spacing between the first and the second windings is shortened so that a coupling of the magnetic field of the first winding with the second winding is varied. For example, if an alternating current is used in the first winding, when no force is applied a voltage is induced and once a force is applied a change in this voltage can be detected.

This effect may be used to define an input operation of a user. For example, a threshold of a voltage value may be defined, which lies in between a voltage induced when no force is applied and a voltage induced when a force is applied. Therefore, once the measuring section 340 measures that an induced voltage value is larger than the threshold value, it is determined that the user presses down the cover layer performing the input operation. Consequently, the voltage measurement by the measuring section 340 may determine the presence of a finger, a hand or a stylus on the touch area or its absence.

As described above, when using an alternating current, the voltage induced will be an AC voltage in the second winding 330. Therefore, it is preferable to amplify and low-pass filer this voltage to achieve a stable DC voltage value. This may be performed in the determination section 345, in which a signal level based on the induced voltage is determined depending on the extent of the change in the spacing.

For example, the signal level may correspond to the stable DC voltage value so that the signal level represents the extent of the change in the spacing which is proportional to the magnitude of the force. To measure a change in the induced voltage and determine a change in a signal level, it is assumed that the alternating current is kept constant.

The output of the determination section 345 is then provided to the controller 380 to trigger a function of a device, as described above. For example, the controller may switch on the display assembly 420 in FIG. 4 when a touch is sensed.

As indicated by the dashed line in FIGS. 3 and 4, in another embodiment, the output from the measurement section is directly input in the controller 380 which may perform similar function as the determination section 345.

The touch sensor 390 of the touch sensing device 300, shown in FIG. 3, is placed between the cover layer 310 and the first and second windings 320, 330 to sense a position touched on said touch area, e.g. x,y-coordinates on the touch area. The touch sensor 390 may be a conventional touch sensor known in the art having capacitive components in a first and a second layer to provide a matrix structure enabling to obtain the x,y-coordinates of the location where a user touches the touch area. Since several different kinds of conventional touch sensors are well-known to the skilled person, a more detailed description will be omitted.

Therefore, in addition to one or more input parameters in the z-direction, also an x,y-position may be obtained as an input parameter to the touch sensing device. Consequently, the touch sensing device may be used as a force-sensitive touch pad of or in another device to trigger different functions depending on the position touched and the magnitude of the force exerted by the touch.

For example, if the touch sensing device is combined with a display, a user may select an object at a specific x,y-coordinate by pressing on the touch area corresponding to the coordinate with a force F₁ to select the object and by pressing stronger with a force F₂ the object my be cut or copied. On the other hand, the user may press another x,y-coordinate with the force F₁ and may paste the object to this position by pressing with the force F₂. Several other drag and drop or copy and paste applications can be implemented with a simple configuration using x,y,z-input parameters. Therefore, in addition to the input operations of a known touch sensor one additional input dimension is added, which can be used to trigger several different functions depending on several different forces applied to the touch area.

Returning to FIG. 3, the power supply 385 in FIG. 3 is connected to the first winding 320. In one example, the power supply 385 supplies an alternating current to the first winding 320, for which an oscillator may be used.

Further, the touch sensing device 300 comprises the controller 380 connected to the power supply 385, the touch sensor 390 and the determination section 345.

In one embodiment, the controller 380 controls the supply of current to the first winding 320. In particular, the controller may supply the current depending on whether the touch sensor 390 senses a touch or not. For example, if a touch is sensed by the touch sensor 390, a current is supplied to the first winding 320 so that also the force of the touch in z-direction can be estimated. In other words, the force sensing system comprising the two windings is only activated as long as there is a finger, a hand, a stylus or other object present on the touch area. Therefore, power may be saved, since the first winding 320 is only energised when the touch area is touched by switching on/off the current.

As described above, if an alternating current is supplied to the first winding this results in an induced alternating voltage in the second winding and a change in this voltage on the side of the second winding is produced if the spacing between the windings is changed due to an external force, for example. Similar to the touch sensing device 100, the spacing of the touch sensing device 300 between the first winding and second winding can be as small as 0.05 mm and preferable somewhere in between 0.1 mm and 0.2 mm so as to allow a thin spacing and a thin touch sensing device. Thickness is particularly reduced, if also the first winding and the second winding are wound to expand in a plane substantially parallel to the cover layer 310 and the two windings 320 and 330.

Depending on the location of the electronics in the touch sensing device, such as controller and wirings, the first winding and the second winding can be shielded by a thin metallic foil which will not affect the magnetic field of the first winding or of the second winding but may still reduce electronic noise in the system depending on its location.

It is clear that the touch sensing device 100 or 300 is not limited to only two windings but also more than two windings may be used if desired. For example, three windings may be used, wherein the middle winding can be supplied with a current and a voltage is induced in the upper and lower winding so as to achieve a stronger inductive effect.

In one embodiment, four pairs of windings, i.e. four first windings and four second windings may be placed in the four corners of the touch sensing device, e.g. below the four corners of the cover layer. This arrangement allows, in addition to a z-direction measurement, also estimating the position where the force is applied. For example, if a much larger deflection is measured in one corner than in the other three corners, this indicates that the position to which the force has been applied is close to the one corner. Therefore, using a suitable algorithm the position in x,y-coordinates may be derived solely with the help of windings and induction measurements and without the use of a capacitive or resistive touch sensor as known in the art.

In the following, in FIG. 4, the touch sensing device 300 is combined with a display assembly to constitute a touch screen device 400. The display assembly 420 may comprise any kind of display, such as an LCD (liquid crystal display) or OLED-(organic light emitting diode) display.

In the embodiment of FIG. 4, the cover layer 410 is at least partially made of a transparent material, i.e. a light-transmissive material, allowing to view or read the display of the display assembly underneath. Similar to the discussion with respect to FIG. 1B, the cover layer 410, which may comprise a glass or plastic window in front of the display of the display assembly, can be made of a flexible and preferably resilient material but is not limited thereto. In case of a flexible cover layer 410, the display assembly is also flexible to change the spacing between the windings as described with respect to FIG. 1B.

However, if the cover layer and the display assembly are stiff and rigid, at least one of these elements may be connected to elastic sidewalls, shown in FIG. 4, which are adopted to change their height depending on the force applied to the cover layer.

It is noted that the touch sensor 390 itself may form the cover layer 310 or 410. For example, a layer including a pattern of electronically conductive material such as ITO (indium tin oxide) may be contained in the cover layer, which is conventionally used for touch sensors.

In another embodiment, the touch sensing device 100 or 300 or the touch screen device 400 is incorporated in a mobile device, such as a cellular phone or other type of mobile phone, or a portable computer. The applications of the touch sensing device or touch screen device are clearly not limited to mobile devices but incorporation in mobile devices is particular advantageous, since these devices are usually small and require intelligent user interfaces or man-machine interfaces to trigger various functions. Therefore, incorporating the touch sensing device or touch screen device, which can be made as small as 0.5 mm, in a mobile device is highly advantageous.

The description above has mentioned several individual elements, such as the controller 380, determination section 345, measuring section 340, etc., and it should be understood that the invention is not limited to these elements as structural units but these elements should be understood as elements comprising different functions. In other words, it is understood by the skilled person that an element in the above-described embodiments is not construed as being limited to a separate tangible part but is understood as a kind of functional entity so that several functions may also be provided in one tangible part. For example, the function of the determination section 345 may also be integrated in the controller 380.

Moreover, the physical entities according to the invention and/or its embodiments may comprise or store computer programmes including instructions such that, when the computer programmes are executed on the physical entities, steps, procedures and functions of these elements are carried out according to embodiments of the invention. The invention also relates to computer programmes for carrying out the function of the elements, and to a computer-readable medium storing the computer programmes for carrying out methods according to the invention.

The above-described elements of the touch sensing devices 100 and 300 as well as of the touch screen device 400 may be implemented in hardware, software, field-programmable gate arrays (FPGAs), application-specific integrated circuits (ASICs), firmware or the like.

It will be appreciated that various modifications and variations can be made in the described elements, touch sensing devices, touch screen device, mobile devices and methods as well as in the construction of this invention without departing from the scope or spirit of the invention. The invention has been described in relation to particular embodiments which are intended in all aspects to be illustrative rather than restrictive. Those skilled in the art will appreciate that many different combinations of hardware, software and firmware are suitable for practicing the invention.

Moreover, other implementations of the invention will be apparent to the skilled person from consideration of the specification and practice of the invention disclosed herein. It is intended that the specification and the examples are considered as exemplary only. To this end, it is to be understood that inventive aspects may lie in less than all features of a single foregoing disclosed implementation or configuration. Thus, the true scope and spirit of the invention is indicated by the following claims.

1. A touch sensing device, comprising
a cover layer defining a touch area;
a first winding placed on one side of said cover layer and extending over at least a part of said touch area; and
a second winding placed on the same side of said first winding, and being spaced apart from said first winding, wherein
said first and second windings and said cover layer are arranged so that a coupling of a magnetic field generated by a current supplied to said first winding varies in response to a force onto the touch area.

2. The touch sensing device of claim 1, further comprising
a measuring section for measuring a voltage of said second winding induced by said current supplied to said first winding and a change in said spacing between said first and second windings due to said force.

3. The touch sensing device of claim 2, further comprising
a determination section for determining a signal level based on the induced voltage depending on the extend of said change in said spacing.

4. The touch sensing device of claim 1, further comprising a touch sensor being placed between said cover layer and said first and second windings to sense a position touched on said touch area.

5. The touch sensing device of claim 1, further comprising a controller to control supply of said current to said first winding depending on whether a touch sensor senses a touch or not.

6. The touch sensing device of claim 4, wherein said current is supplied to said first winding if a touch is sensed by said touch sensor.

7. The touch sensing device of claim 1, wherein said current to be supplied to said first winding is an alternating current or direct current.

8. The touch sensing device of claim 7, wherein said alternating current to be supplied to said first winding results in an induced alternating voltage in said second winding so as to produce a change in voltage on the side of said second winding if said spacing is changed.

9. The touch sensing device of claim 1, wherein said spacing between said first winding and second winding is between 0.05 mm and 0.3 mm, and preferably between 0.1 mm and 0.2 mm.

10. The touch sensing device of claim 1, wherein at least one of said first winding and second winding expands in a plane.

11. The touch sensing device of claim 1, wherein at least one of said first winding and second winding is shielded by a thin foil.

12. The touch sensing device of claim 1, wherein said second winding is placed between said cover layer and said first winding.

13. The touch sensing device of claim 1, wherein the cover layer is at least partly made of a transparent material

14. Touch screen device comprising said touch sensing device of claim 1 and a display assembly between said cover layer and said first and second windings.

15. Mobile device comprising said touch sensing device of claim 1.

16. Method for sensing a touch on a touch sensing device with a touch area and a first and a second winding, comprising the steps
supplying a current to said first winding;
applying a force onto said touch area to vary a coupling of a magnetic field generated by said current so as to induce a voltage in said second winding; and
determining a signal level based on said induced voltage.
